(19) United States
(12) Patent Application Publication
(10) Pub. No.: US 2024/0282517 A1
(43) Pub. Date: Aug. 22, 2024

(54) Method For Manufacturing Electrical Devices

(71) Applicant: Hutchinson Technology Incorporated, Hutchinson, MN (US)

(72) Inventors: Collin M. Grove, Hillsboro, OR (US); Tyler D. Keeler, Eau Claire, WI (US); Bryan J. Scheele, Hutchinson, MN (US)

(21) Appl. No.: 18/444,513

(22) Filed: Feb. 16, 2024

Related U.S. Application Data
(60) Provisional application No. 63/447,584, filed on Feb. 22, 2023.

(51) Int. Cl. H01F 41/12; H05K 3/10; H05K 3/46

(52) U.S. Cl. CPC H01F 41/125; H05K 3/10; H05K 3/4608; H05K 2203/1105; H05K 2203/162

(57) ABSTRACT

An improved method for manufacturing an electrical device is described herein. In some embodiments according to the present disclosure, the method includes: providing a base layer with a coil set, thermal flattening the base layer, and forming a circuit on the base layer opposite of the coil set in the base layer.

### CROSS-REFERENCE TO RELATED APPLICATIONS

This application claims the benefit of, and priority to, U.S. Provisional Application No. 63/447,584 filed on Feb. 22, 2023, which is hereby incorporated by reference in its entirety.

### TECHNICAL FIELD

Embodiments of the present disclosure relate generally describe electrical devices. In some embodiments, the present disclosure relates to methods of manufacturing circuits onto substrates, which may be used in a large variety of electrical devices, such as flexures, suspensions and other components used in hard disk drives (HDDs), sensors, actuators or voice coil motors used in autofocusing or optical image stabilization, and other electrical devices.

### BACKGROUND

Base materials supplied for electrical devices, such as circuits formed on substrates, generally have a coil set being introduced during the age-hardening process. In such instance, these base materials generally have poor flatness. Because the base materials provided for the base layer in electrical devices have poor flatness, conventional methods for producing electrical devices are unable to meet the process requirement for flatness.

There remains a continuing need for a method for producing electrical devices with improved flatness, i.e., the ability to produce an electrical device within a certain flatness tolerance range or specification limits.

### SUMMARY

Broadly, embodiments of the present disclosure provide an improved method for manufacturing an electrical device.

In some embodiments according to the present disclosure, the method includes: providing a base layer with a coil set, thermal flattening the base layer, and forming a circuit on the base layer opposite of the coil set in the base layer.

In some embodiments according to the present disclosure, forming the circuit on the base layer includes forming a dielectric layer opposite of the coil set.

In some embodiments according to the present disclosure, forming the circuit on the base layer includes forming a trace layer on the dielectric layer opposite of the coil set.

In some embodiments according to the present disclosure, the base layer is a stainless steel base or a metal base layer.

In some embodiments according to the present disclosure, the metal base layer is made of Cu or Cu alloy.

In some embodiments according to the present disclosure, the dielectric layer is a layer of polyimide.

In some embodiments according to the present disclosure, the trace layer is made of Cu or Cu alloy.

In some embodiments according to the present disclosure, the thermal flattening of the base layer includes wrapping the base layer around a core against the coil set.

In some embodiments according to the present disclosure, the core is a 10 inch to 30 inch diameter core.

In some embodiments according to the present disclosure, the core is a 12 inch to 24 inch diameter core.

In some embodiments according to the present disclosure, the core is a 12 inch to 18 inch diameter core.

In some embodiments according to the present disclosure, the thermal flattening of the base layer includes heating the base layer at 300° C. to 500° C.

In some embodiments according to the present disclosure, the heating the base layer is at 350° ° C. to 450° ° C.

In some embodiments according to the present disclosure, the heating the base layer is at 370° ° C. to 420° C.

In some embodiments according to the present disclosure, the heating the base layer is performed for 20 to 200 minutes.

In some embodiments according to the present disclosure, the heating the base layer is performed for 50 to 150 minutes.

In some embodiments according to the present disclosure, the heating the base layer is performed for 80 to 120 minutes.

In some embodiments according to the present disclosure, the electrical device has a flatness of 10 μm to 40 μm.

### BRIEF DESCRIPTION OF THE DRAWINGS

The accompanying drawings, which are incorporated in and constitute a part of this specification, exemplify various embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not generally drawn to scale.

FIG. 1 shows a cross-sectional view of a conventional electrical device with the circuit disposed on the coil set of the base layer and an electrical device with the circuit disposed opposite of the coil set according to some embodiments of the present disclosure.

FIG. 2 is a schematic diagram showing one example of a technique to measure flatness achieved by methods of the present disclosure using two planes to measure points around a profile of a device to determine flatness.

FIGS. 3A and 3B illustrate another technique to measure flatness achieved by methods of the present disclosure of a coil type device showing a series of points around an outer region of the device that are measured to determine an outer flatness.

### DETAILED DESCRIPTION

An improved method for manufacturing an electrical device is disclosed herein. The method described herein allows for the manufacture of electrical devices with improved flatness without sacrificing the mechanical and electrical properties of the electrical devices.

In some embodiments, the electrical device is a suspension component such as a flexure having high-quality signal performance. In some embodiments, the electrical device is a flexure for a head suspension, e.g., a dual stage actuation (DSA) suspension. In some embodiments, the flexure is mounted to a stainless steel load beam.

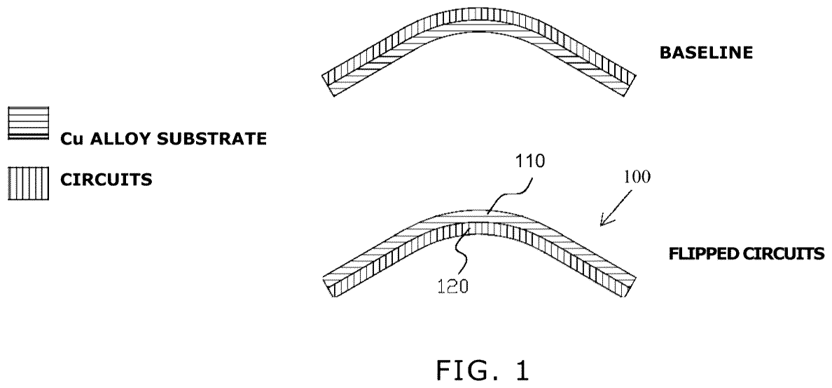

In some embodiments, the method includes providing a base layer with a coil set, thermal flattening the base layer, and forming a circuit on the base layer opposite of the coil set in the base layer. In some embodiments, forming the circuit on the base layer includes forming a dielectric layer opposite of the coil set. In some embodiments, forming the circuit includes forming a trace layer on the dielectric layer opposite of the coil set. FIG. 1 shows forming the circuit 120 on the base layer opposite of the coil set on the base layer 110 of an electrical device 100. Conventional methods form the circuit on the coil set of the base layer and not opposite of the coil set.

The electrical device can comprise a base layer, a trace layer, and a dielectric layer separating the trace layer from the underlying base layer. In some embodiments, the base layer can be a stainless steel base or a metal base layer. In some embodiments, the metal base layer can be made of Cu or Cu alloy. In some embodiments, the dielectric layer can be a layer of polyimide or other insulating material. In some embodiments, the traces can be formed from copper, copper alloys or other conductors.

In some embodiments, the thermal flattening of the base layer includes wrapping the base layer around a core against the coil set. In some embodiments, the core is a 10 inch to 30 inch diameter core. In some embodiments, the core is a 12 inch to 26 inch diameter core, 12 inch to 24 inch diameter core, or 12 inch to 20 inch diameter core. In some embodiments, the core is a 12 to 18 inch diameter core. In some embodiments, the core is a 16 inch diameter core.

In some embodiments, the thermal flattening of the base layer further includes heating the base layer at 300° ° C. to 500° C. In some embodiments, heating the base layer can be at 300° C. to 450° C., 310° ° C. to 450° ° C., 320° ° C. to 450° ° C., 330° ° C. to 450° ° C., 340° ° C. to 450° C., 350° C. to 450° ° C., 360° ° C. to 450° ° C., 360° ° C. to 440° ° C., 370° C. to 430° C., or 380° ° C. to 420° C. In some embodiments, heating the base layer can be at 375° C. to 425° C. In some embodiments, heating the base layer can be at 400° C.

In some embodiments, heating the base layer at the above temperature ranges can be performed for 20 minutes to 200 minutes. In some embodiments, heating the base layer can be done for 40 to 180 minutes, 60 to 180 minutes, 60 to 160 minutes, 80 to 140 minutes, 20 to 180 minutes, 30 to 170 minutes, 40 to 160 minutes, 50 to 150 minutes, 60 to 140 minutes, 70 to 130 minutes, 80 to 120 minutes, or 90 to 110 minutes. In some embodiments, heating the base layer can be for 100 minutes.

In some embodiments, heating the base layer can be at 350° C. to 450° ° C. can be done for 80 to 120 minutes. In some embodiments, heating the base layer can be at 375° C. to 425° C. can be done for 80 to 120 minutes. In some embodiments, heating the base layer is performed at 400° ° C. for 100 minutes.

Importantly, heating the base layer as described above does not overage the base layer, which would undesirably allow for too much growth of precipitates in the base layer, thereby causing a loss of strength and hardness.

In some embodiments, it is desired that thermal flattening of the base layer is performed prior to forming the circuit on the base layer. Thermal flattening of the base layer during or after forming the circuit on the base layer will increase the risk of degradation of the electrical device. For example, the dielectric layer experienced discoloration when heated at 400° C. Therefore, thermal flattening of the base layer occurs before the steps for forming the circuit on the base layer opposite of the coil set.

Subtractive and additive processes can be used to manufacture these devices. Subtractive manufacturing methods use photolithography and etching processes to form the electrical device, e.g., a suspension component like a flexure, from laminated material stock having a layer of stainless steel (or other metal) and a layer of conductive material separated by an insulating layer. Additive manufacturing methods use photolithography, deposition and etching processes to add the insulating layer, traces and other structures to a stainless steel or metal base.

In some embodiments, an additive process can be used to fabricate the electrical device after providing the base layer and thermal flattening the base layer. The insulating layer can be formed over the base layer against the coil set. In some embodiments, the insulating layer is formed by coating, curing and patterning a polyimide precursor. Other materials and processes are used in other embodiments.

In some embodiments, the trace layer is formed on the insulating layer disposed against the coil set. In some embodiments, a seed layer of conductive material is sputtered onto the insulating layer and patterned using photolithography and etching processes. The traces are then electroplated onto the seed layer. Any conductive plating layer can then be plated onto the traces. Photolithography and other processes such as vapor deposition and chemical etching can also be used to form the traces on the insulating layer. A dielectric cover layer can be formed over the traces using materials and processes such as those described above for forming the insulating layer.

It was found that the dielectric curing process was impacting flatness. By forming the dielectric or insulating layer on the opposite side of the coil set in the base layer, it was found that the dielectric curing process would counteract the coil set. However, it was found that this dielectric curing process of the dielectric or insulating layer on the opposite side of the coil set in the base layer was not enough to consistently meet desired flatness tolerances or requirements, i.e., the ability to produce an electrical device within a certain flatness tolerance range or specification limits.

The method described herein according to some embodiments of the present disclosure includes the combination of thermal flattening the base layer and subsequently forming a dielectric layer opposite of the coil set in the base layer, which improves flatness, meaning that the process is capable and meets flatness specification limits.

In addition, conventional methods for manufacturing electrical devices, like a suspension component, produce an electrical device having a flatness value of 60 μm to 100 μm. The improved method described herein according to some embodiments of the present disclosure improves a flatness value for these electrical devices to 10 μm to 40 μm. In some embodiments, methods as described herein can provide improvements in the average flatness across an electronic device, such as a coil, by a value in the range of approximately % to [70]%. For instance in one example, the initial average flatness of a device was measured to be approximately 0.000070 μm. After treatment of the device using the methods of the present disclosure, the average flatness of the device was measured to be approximately 0.000025 μm or less. In other embodiments, after processing electrical devices accordingly to methods of the present invention, the average flatness of the electrical device can be in the range of approximately [0.000070] μm to [0.000025] μm.

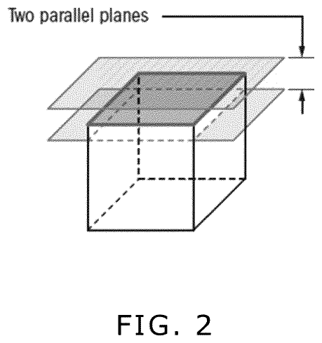

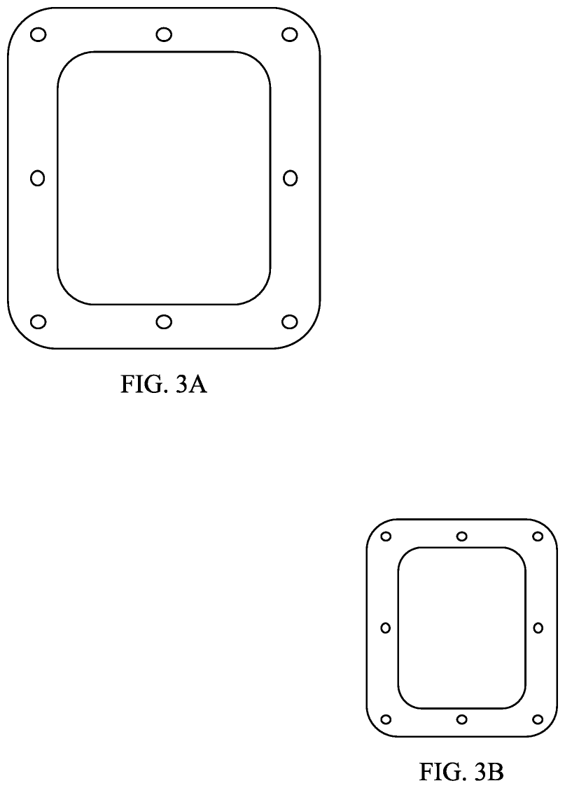

In some instances, to measure a flatness as described herein, two planes can be created, and points around the part profile can be measured as shown in FIG. 2. The largest difference can be used to determine the reported flatness. In some embodiments, methods of the present embodiments can provide improvement in the flatness across the profile. For instance, one can select a series of points around an outer region of the device to be measured to generate an outer flatness as shown in FIGS. 3A and 3B. As illustrated in FIGS. 3A and 3B, a series of “B” points are selected along the outer profile of the device. All or a select group of the B points measurement may be used to generate the outer flatness data.

The method for forming electrical devices including the combination of thermal flattening the base layer and subsequently forming a dielectric layer opposite of the coil set in the base layer does not change the properties of the base layer. Therefore, not only are the mechanical and electrical properties of the electrical devices are not affected by the flattening process described herein, the electrical devices exhibit an improved flatness.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

We claim:

1. A method for manufacturing an electrical device, comprising:
providing a base layer with a coil set,
thermal flattening the base layer, and
forming a circuit on the base layer opposite of the coil set in the base layer.

2. The method according to claim 1, wherein the forming the circuit on the base layer includes forming a dielectric layer opposite of the coil set.

3. The method according to claim 2, wherein the forming the circuit on the base layer includes forming a trace layer on the dielectric layer opposite of the coil set.

4. The method according to claim 1, wherein the base layer is a stainless steel base or a metal base layer.

5. The method according to claim 1, wherein the metal base layer is made of Cu or Cu alloy.

6. The method according to claim 2, wherein the dielectric layer is a layer of polyimide.

7. The method according to claim 3, wherein the trace layer is made of Cu or Cu alloy.

8. The method according to claim 1, wherein the thermal flattening of the base layer includes wrapping the base layer around a core against the coil set.

9. The method according to claim 8, wherein the core is a 10 inch to 30 inch diameter core.

10. The method according to claim 8, wherein the core is a 12 inch to 24 inch diameter core.

11. The method according to claim 8, wherein the core is a 12 inch to 18 inch diameter core.

12. The method according to claim 1, wherein the thermal flattening of the base layer includes heating the base layer at 300° C. to 500° C.

13. The method according to claim 12, wherein the heating the base layer is at 350° C. to 450° C.

14. The method according to claim 12, wherein the heating the base layer is at 370° C. to 420° C.

15. The method according to claim 12, wherein the heating the base layer is performed for 20 to 200 minutes.

16. The method according to claim 15, wherein the heating the base layer is performed for 50 to 150 minutes.

17. The method according to claim 15, wherein the heating the base layer is performed for 80 to 120 minutes.

18. The method according to claim 1, wherein the electrical device has a flatness of 10 μm to 40 μm.

19. The method according to claim 1, wherein the electrical device exhibits improvement in the average flatness measured by creating two planes and measuring points around the part profile to determine the average flatness of the electrical device.

20. The method of claim 1, wherein the electrical device exhibits improvement in average flatness measured by identifying a series of “B” points along the outer profile of the device and measuring a plurality of the B points.
